(19) United States
(12) Patent Application Publication
(10) Pub. No.: US 2026/0305498 A1
(43) Pub. Date: Oct. 1, 2026

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Andrea ALBERTINETTI, Bouskoura Green Town (MA); Reiner Alvaran MAGHIRANG, Bouskoura (MA)

(73) Assignee: STMicroelectronics International N.V., Geneva (CH)

(21) Appl. No.: 19/573,375

(22) Filed: Mar. 20, 2026

(30) Foreign Application Priority Data
Mar. 25, 2025 (IT) 102025000006159

(51) Int. Cl. H10W 90/00; H10W 70/40; H10W 72/00; H10W 90/10

(52) U.S. Cl. CPC H10W 90/736; H10W 70/465; H10W 72/07302; H10W 72/07336; H10W 90/10; H10W 72/884; H10W 90/753; H10W 90/756

(57) ABSTRACT

A first semiconductor die and a second semiconductor die are attached to first and second die mounting regions, respectively, of a surface of a substrate via reflow of solder material provided at the first and second die mounting regions. The surface of the substrate includes a clearance area between the first and second die mounting regions. Movement of the first and second semiconductor dice in the clearance area in response to reflow of the solder material provided at the first and second is contained via raised containment formations at the clearance area on the surface of the substrate.

### PRIORITY CLAIM

This application claims the priority benefit of Italian Application for Patent No. 102025000006159 filed on Mar. 25, 2025, the content of which is hereby incorporated by reference in its entirety to the maximum extent allowable by law.

### TECHNICAL FIELD

The description relates to semiconductor devices.

One or more embodiments can be applied to power semiconductor devices or modules, for instance.

### BACKGROUND

Semiconductor devices may comprise more than one (integrated circuit, IC) semiconductor chips or dice arranged on a substrate. The semiconductor dice may be mounted on a surface of the substrate via soldering for instance, facilitated by solder material provided onto the surface of the substrate.

A reflow step may be performed in order to form a solder joint between the semiconductor dice and the substrate onto which they are arranged. During reflow, the semiconductor dice may undesirably move in response to evaporation of flux that is provided with the solder material. This may result in contact between two semiconductor dice arranged adjacently on a substrate, that may cause damage to the semiconductor dice.

Reference is made to United States Application for Patent Nos. 2023/0326880 A1, 2023/0197669 A1, 2022/0009247 A1, and 2023/0005825 A1, and U.S. Pat. No. 12,119,321 B2, incorporated by reference, which provide background information in the related technological area.

There is a need in the art to overcome the drawbacks discussed in the foregoing.

### SUMMARY

One or more embodiments relate to a method.

One or more embodiments relate to a corresponding semiconductor device.

In solutions as described herein two semiconductor dice are arranged at two adjacent die mounting regions of a substrate having raised containment formations between the two adjacent die mounting regions that contain movement of the semiconductor dice.

In solutions as described herein, rod-like raised containment formations or structures may be formed with relatively small footprint on the substrate.

In solutions as described herein, the substrate may comprise further raised containment formations between a connection region configured to have a connector attached thereon and a die mounting region.

In solutions as described herein, the raised containment formations may be formed via laser induced forward transfer (LIFT) technique.

### BRIEF DESCRIPTION OF THE DRAWINGS

One or more embodiments will now be described, by way of example only, with reference to the annexed figures, wherein:

FIGS. 1A and 1B are cross-sectional views illustrative of the structure of a semiconductor device;

FIGS. 2A and 2B are plan views illustrative of possible issues in a semiconductor device as illustrated in FIGS. 1A and 1B;

FIGS. 3A and 3B are plan views illustrative of processing steps according to embodiments of the present description; and

FIG. 4 is a plan view illustrative of a device according to further embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

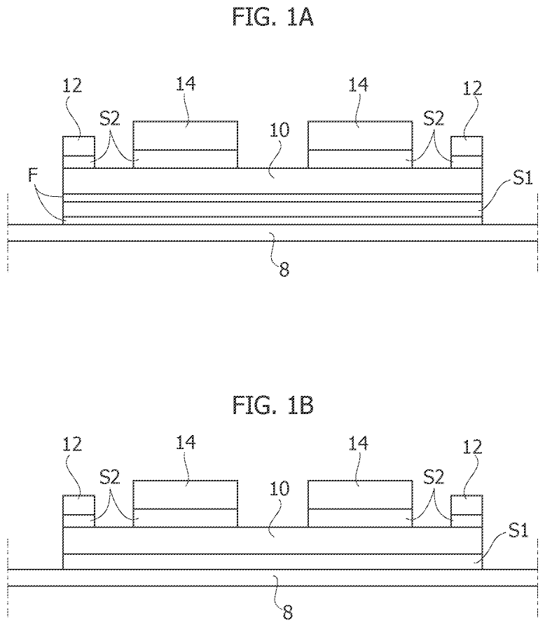

FIGS. 1A and 1B are cross-sectional views illustrative of processing steps in the manufacturing process of a semiconductor device such as a power module, for instance.

As illustrated in FIG. 1A, the device comprises: a substrate 10, and two or more integrated circuit (IC) semiconductor dice 14 arranged on the substrate 10.

In the exemplary device illustrated in the figures, the substrate 10 is arranged onto a (portion of a) leadframe 8. In a device as considered herein, several substrates (or substrate portions) 10 having arranged thereon a respective set of (IC) semiconductor dice 14 may be arranged at corresponding mounting regions of a leadframe 8.

The designation “leadframe” (or “lead frame”) is currently used (see, for instance the USPC Consolidated Glossary of the United States Patent and Trademark Office) to indicate a metal frame (copper, for instance) that provides support for one or more integrated circuit (IC) chip or die (the terms chip/chips and die/dice are herein regarded as synonymous) as well as electrical leads or contacts to interconnect the integrated circuit in the die or chip to other electrical components or contacts.

Essentially, a leadframe comprises an array of electrically-conductive formations (or leads, not visible in the figures for simplicity) that from an outline location extend inwardly in the direction of one or more semiconductor chips or dice thus forming an array of electrically-conductive formations from a die pad or a substrate configured to have at least one semiconductor die attached thereon.

The substrate 10 may be any substrate of the type currently used in power devices/modules, for instance, such as a direct bonded copper (DBC) substrate, or an active metal brazed (AMB) substrate.

As illustrated, electrical contacts may be provided at the top surface of the substrate 10 and are configured to be electrically coupled to the semiconductor dice 14.

In a power semiconductor device or module, the current transferred from the high-power section (the two semiconductor dice 14 illustrated in the figures, for instance) to the output pads or connectors 12 of the device/module can be significant and ribbons or clips are used for that purpose in the place of wires. Wires can still be used to provide electrical coupling to a low-power section (a controller, for instance) in the device.

Still referring to FIG. 1A, the various components in the assembly illustrated in the figure may be assembled or mounted via soldering facilitated by solder material S1, S2 at the interface between the components and the substrate 10.

More in detail, a first solder material S1 (tin or a tin alloy, for instance) may be provided between the surface of the leadframe 8 and a bottom surface of the substrate 10; as illustrated, the solder material may be provided as a solder preform sandwiched between layers of flux F, in order to facilitate soldering of the substrate 10 and the leadframe 8.

Further solder material S2 may be used to attach the semiconductor dice 14 and the connectors 12 to the substrate 10. The further solder material S2 may be a solder paste, comprising a mixture of solder material and flux, for instance.

The assembly may be transferred into an oven in order to perform a reflow step to facilitate forming the solder joints between the various components in the assembly; the resulting device is illustrated in FIG. 1B. As illustrated, the flux F may evaporate in response to the reflow step. This may also be the case for the flux comprised in the solder paste S1. FIG. 1B is thus exemplary of two semiconductor dice 14 attached at respective mounting regions of a substrate via reflowed solder material.

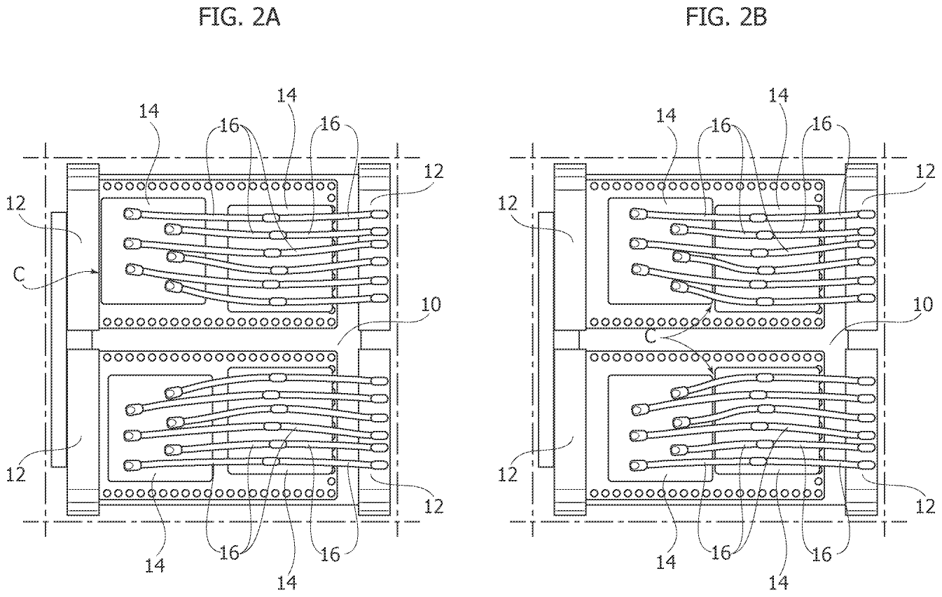

Further processing may comprise providing electrically conductive ribbons (visible in FIGS. 2A and 2B and indicated therein with the reference 16) to electrically couple two adjacent semiconductor dice or a semiconductor die 14 and an adjacent connector 12. Each electrically conductive ribbons 16 have a first terminal portion thereof welded/bonded at a die bonding pad (that is, pads providing electrical contact points to the integrated circuit embedded in the die 14, not visible in the figures for simplicity) at the top/front surface of a semiconductor die 14 and a second terminal portion welded/bonded at a connector 12 (for ribbons 16 providing die-to-connector coupling) or to a die bonding pad of a second semiconductor die 14 (for ribbons 16 providing die-to-die coupling).

FIGS. 2A and 2B are plan views illustrative of the assembly resulting from the processing steps described in the foregoing.

In a reflow step as conventional in the art, melting of the solder material S1 or solder paste S2 may cause the components to move. In particular, the semiconductor dice 14 have been observed to move considerably during reflow, in response to evaporation of flux comprised in the solder paste S2, for instance.

In relatively small devices, the distance between two adjacent dice 14 or the distance between a die 14 and a connector 12 may be small and movement of the dice may cause two adjacent dice or the die and the connector to collide or contact. These issues are illustrated in FIGS. 2A and 2B. In particular, in the device illustrated in FIG. 2A one semiconductor die 14 undesirably contacts with an adjacent connector 12 at the point indicated with the reference C. Similarly, FIG. 2B is illustrative of the possible, undesired contact between two adjacent semiconductor dice 14 (at points indicated with the reference C) caused by movement of the dice 14 during reflow.

Contact or collision between two adjacent dice 14 or between a die 14 and a connector 12 may cause formation of a solder fillet that reaches the active (top/front) surface of a semiconductor die 14; this may cause undesired short circuits between two die bonding pads at the active surface of the die 14 or between a die bonding pad and a connector 12. Moreover, contact between two dice 14 (as illustrated in FIG. 2B, for instance) may cause mechanical stress to develop in the semiconductor material of the dice 14 which may result in formation of cracks, possibly worsened by further mechanical stress induced by thermal expansion of the dice 14 (during operation of the device or during test thermal cycles, for instance).

It is noted that issues as described in the foregoing may cause rejection of the device, thus undesirably reducing the yield of the manufacturing process of such devices.

In order to reduce the risk of undesired contact between adjacent dice (or between a die and a connector) a relatively large clearance area is provided between the adjacent dice 14, in order to allow for some degree of movement of the dice. However, such a relatively large clearance area negatively affects size and dimensions of the substrate 10 and/or the package of the final device, increasing cost and footprint of the device.

According to one approach, solder stoppers or solder grooves may be provided at the mounting surface of the substrate 10 in order to contain the undesired spreading of solder material during reflow; while being beneficial in reducing the risk of short circuits due to the spreading of solder material, such approach has been observed to be inadequate in countering contact or collision between two adjacent dice (or between a die and a connector). Moreover, solder stoppers/grooves are relatively large features provided in the substrate 10 (at the surface thereof) which do not facilitate reducing the size of the substrate 10.

Solutions as described herein aim at reducing the risk of contact between two adjacent semiconductor dice during reflow of solder material used to attach the dice.

In solutions as described herein two semiconductor dice are arranged at two adjacent die mounting regions of a substrate having raised containment formations formed at a clearance area between the two adjacent die mounting regions.

In solutions as described herein, the substrate may comprise further raised containment formations between a connection region configured to have a connector attached thereon and a die mounting region.

In solutions as described herein, the raised containment formations may be formed via laser induced forward transfer (LIFT) technique.

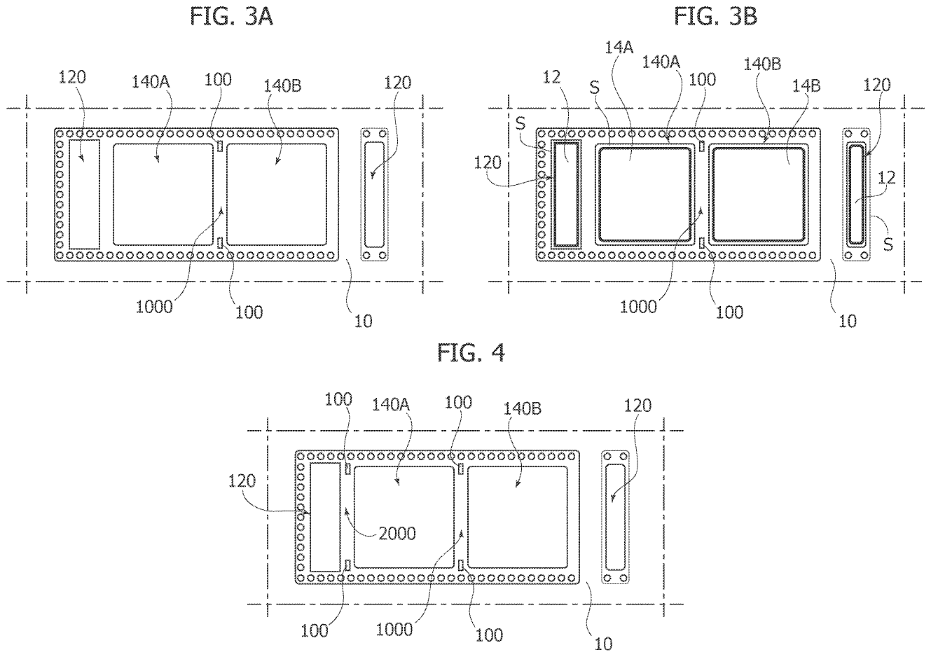

FIGS. 3A and 3B are plan views illustrative of processing steps in manufacturing a semiconductor device according to the present description.

FIG. 3A is illustrative of a substrate 10 for semiconductor device, of the type suitable for power devices, for instance (such as an AMB or DBC substrate).

The substrate 10 exemplified in FIG. 3A is configured to have first and second (integrated circuit (IC)) semiconductor dice arranged at respective first 140A and second 140B die-mounting regions of the surface of the substrate 10. It is noted that solutions according to the present description may also be applied to substrate 10 configured to host more than two dice. For instance, FIG. 3A may be illustrative of a portion of a substrate 10 configured to host, in a general case, a set of semiconductor dice.

Still referring to FIG. 3A, the surface of the substrate 10 may comprise, in addition to the die-mounting regions 140A, 140B, connection regions 120 configured to have respective connectors (connectors 12 as exemplified in FIGS. 1A and 1B, for instance) mounted thereon.

As discussed previously, a solder paste or a solder preform may be used to attach semiconductor dice and connectors to respective die-mounting regions 140A, 140B and connection regions 120 (possibly with additional flux provided thereon).

As illustrated, the first and second die-mounting regions 140A, 140B lie adjacent to each other, with a clearance area 1000 between the first and second die-mounting regions 140A, 140B.

In one or more embodiments, raised containment formations or structures 100 are formed at the clearance area 1000 located between the first and the second die-mounting regions 140A, 140B to the effect of containing movement of dice during reflow that may undesirably lead to contact or collision between the dice.

In one or more embodiments, the raised containment formations 100 may be formed with a height adequate for countering movement of the dice during reflow; raised containment formations 100 having a height of about 50 microns have been observed to adequately contain movement of the dice in the clearance area 1000.

In one or more embodiments, the raised containment formations 100 may be formed as rod-like formations 100. Rod-like formations 100 may be formed with a relatively small horizontal (that is, parallel to the surface of the substrate 10) dimensions in order to reduce the footprint on the surface of the substrate 10. For instance, rod-like formations 100 having linear base dimension of 50 to 100 microns would be desirable in so far as the area occupied by the rod-like formations 100 is relatively small.

By way of example, rod-like formations 100 may be formed with: a square (circular) base with a side (diameter) of about 50 microns, or a rectangular shape having pair of opposite sides of 50 and 100 microns, for instance.

According to embodiments of the present description, (raised) containment formations 100 may be formed via an additive manufacturing technique. The containment formations 100 may be formed by dispensing any material suitable to be dispensed via additive manufacturing techniques.

In one or more embodiments containment formations 100 are formed by dispensing electrically conductive material (a metallic material such as copper, for instance) at selected locations of the clearance area 1000.

When containment formations 100 of electrically conductive material are formed, it may be advantageous to form a coating of electrically insulating material covering the electrically conductive material of the containment formations 100. Such a coating of the containment formations 100 may be formed via the same additive manufacturing technique used to form the containment formations 100. The electrically insulating coating may be desirable when electrical insulation between the dice 14 and the containment formations 100 (and the substrate 10 onto which the containment formations 100 are formed) is desired.

In one or more embodiments, laser induced forward transfer (LIFT) may be used to form the containment formations 100. As per se known in the art, the acronym LIFT denotes a deposition process where material from a donor tape or sheet is transferred to an acceptor substrate (here, the substrate 10) facilitated by laser pulses.

General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

Among the various additive manufacturing techniques, LIFT has been observed to be a particularly advantageous choice in so far as rod-like containment formations 100 with low base to height ratio may be formed in a relatively simple way. Forming rod-like containment formations 100 having linear base dimension base of about 50 to 100 microns and a height of about 50 microns as discussed above, may be easily formed via LIFT.

Now referring to FIG. 3B, a first 14A and a second 14B (IC) semiconductor die are attached at the respective first 140A and second 140B die-mounting regions of the surface of the substrate 10 having containment formations 100 formed thereon.

As discussed previously, attaching the dice 14A, 14B onto the surface of the substrate 10 may comprise: providing solder material S at the first and second die mounting regions 140A, 140B; arranging first and second semiconductor dice 14A, 14B onto the solder material S provided at the respective die mounting regions 140A, 140B; and reflowing the solder material S provided at the respective die mounting regions 140A, 140B having the first and second semiconductor dice 14A, 14B arranged thereon (that is, processing the assembly via a reflow step, in a reflow oven, for instance).

Movement of the first and second dice 14A, 14B during the reflow step is contained by the containment formations 100 formed at the clearance area 1000; in fact, while dice 14A, 14B can still move in response to melting of the solder onto which they are arranged or in response to evaporation of flux (included in a solder paste or additionally provided), collision or contact therebetween is countered by the containment formations 100 at the clearance area 1000.

In embodiments as described with reference to FIGS. 3A and 3B, two rod-like containment formations 100 are formed at the clearance area 1000; two rod-like containment formations 100 as illustrated in the figures are advantageous in so far as they have been observed to effectively counter contact between the first and second dice 14A, 14B with a relatively small area occupied at the surface of the substrate 10. However, it is noted that containment formations 100 having a different shape (a dam-like shape, for instance) and/or a different number of containment formations 100 (for instance, one containment formations or more than two containment formations 100) are also possible choices.

As those skilled in the art may appreciate, containment formations 100 as described in the foregoing facilitate providing substrates 10 with a relatively small clearance area 1000 between two adjacent die mounting regions 140A, 140B without the risk of undesired collision or contact between two adjacent dice. This results in relatively smaller substrates 10 and a higher yield (that is, fewer devices rejected) of the manufacturing process.

The assembly may be further processed to obtain a final device. Such further processing may comprise, for instance: providing die-to-die and/or die-to-connector electrical coupling (via electrically conductive ribbons 16, for instance); and encapsulating the assembly in an electrically insulating molding compound (an epoxy resin, for instance).

In embodiments where a plurality of devices are concurrently processed (for instance, providing a common leadframe 8 having a plurality of substrates 10 arranged thereon), the manufacturing process may comprise a singulation step where the common leadframe 8 (processed as described in the foregoing) is singulated into a plurality of final devices.

FIG. 4 is illustrative of embodiments of the present description wherein containment formations 100 are provided also at a second clearance area 2000 located between a die mounting region 140A and a connection region 120 (that is, the region of the surface of the substrate 10 configured to have a connector 12 attached thereon).

In embodiments as illustrated in FIG. 4: a first set of containment formations 100 (two rod-like containment formations 100, for instance) is provided at the clearance area 1000 between two adjacent die mounting regions 140A, 140B; and a second set of containment formations 100 (again, two rod-like containment formations 100, for instance) is provided at the second clearance area 2000 between a connection region 120 and a die mounting region 140A.

Similarly to what has been discussed previously, first die 14A, second die 14B and (at least) one connector 12 are attached at the respective mounting locations (that is the first die mounting region 140A, the second die mounting region 140B and the connection region 120, respectively) via reflow of solder material S provided thereon.

Movement of the first and second dice 14A, 14B as well as of the connector 12 during reflow is contained by the containment formations 100 formed at the two clearance areas 1000, 2000.

Such embodiments may be advantageous when a relatively small clearance is desired between a connector 12 and a semiconductor die 14A, in order to minimize the size of the substrate 10, for instance, with the risk of contact between a semiconductor die 14A and a connector 12 reduced by the containment effect of the containment formations 100.

In summary, solutions as described herein comprise attaching a first semiconductor die 14A and a second semiconductor die 14B to respective first 140A and second 140B die mounting regions of the surface of a substrate 10 via reflow of solder material S provided at the respective first 140A and second 140B die mounting regions, wherein the surface of the substrate 10 includes a clearance area 1000 between the respective first 140A and second 140B die mounting regions.

Solutions as described herein comprise containing movement of the first and second semiconductor dice 14A, 14B in said clearance area 1000 in response to reflow of the solder material S provided at the respective first 140A and second 140B via raised containment formations 100 at said clearance area 1000 of the surface of the substrate 10.

A device according to the present description, obtainable via solutions as described in the foregoing, for instance, comprises a first semiconductor die 14A and a second semiconductor die 14B attached to respective first 140A and second 140B die mounting regions of the surface of a substrate 10 via reflowed solder material S (that is, solder material treated via a reflow step) provided at the respective first 140A and second 140B die mounting regions, wherein the surface of the substrate 10 includes a clearance area 1000 between the respective first 140A and second 140B die mounting regions, wherein the device includes raised formations 100 at said clearance area 1000 of the surface of the substrate 10.

That is, the device includes raised containment formations 100 at said clearance area 1000 mounted on the surface of the substrate 10 with the first and second semiconductor dice 14A, 14B kept off the clearance area 1000.

In one or more embodiments, a connector 12 is attached to a connection region 120 of the surface of the substrate 10 via reflow of solder material S provided at the connection region 120, wherein the surface of the substrate 10 includes a further clearance area 2000 between the connection region 120 and the first die mounting region 140A. Movement of the first semiconductor die 14A and of said connector 12 in the further clearance area 1000 in response to reflow of the solder material S provided at the first mounting region 140A and at the connection region 120 is contained via raised containment formations 100 at the further clearance area 2000 mounted on the surface of the substrate 10.

In one or more embodiments, the raised containment formations 100 may be formed via an additive manufacturing technique (LIFT, for instance).

The raised containment formations 100 may comprise electrically conductive material or electrically insulating material.

In embodiments wherein the raised containment formations 100 comprise electrically conductive material (copper material, for instance), the raised containment formations 100 of electrically conductive material may be provided with an electrically insulating coating. As discussed previously, an electrically insulating coating may facilitate electrical insulation between the semiconductor dice 14A, 14B and the raised containment formations 100 (and the substrate 10 onto which they are formed).

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
attaching a first semiconductor die and a second semiconductor die to first and second die mounting regions, respectively, of a surface of a substrate via reflow of solder material provided at said first and second die mounting regions, wherein the surface of the substrate includes a clearance area between said first and second die mounting regions; and
containing movement of the first semiconductor die and the second semiconductor die in said clearance area in response to reflow of the solder material provided at said first and second die mounting regions via raised containment formations at said clearance area on the surface of the substrate.

2. The method of claim 1, wherein the raised containment formations include two raised containment formations at the clearance area between said first and second die mounting regions.

3. The method of claim 1, comprising:
attaching a connector to a connection region of the surface of the substrate via reflow of solder material provided at said connection region, wherein the surface of the substrate includes a further clearance area between the connection region and the first die mounting region; and
containing movement of one of the first semiconductor die and the second semiconductor die in said further clearance area in response to reflow of the solder material via further raised containment formations at said further clearance area on the surface of the substrate.

4. The method of claim 3, wherein:
the raised containment formations comprise two raised containment formations at the clearance area between said first and second die mounting regions; and
the further raised containment formations comprise two further raised containment formations at the further clearance area between said connection region and said first die mounting region.

5. The method of claim 1, wherein the raised containment formations comprise rod-like containment formations.

6. The method of claim 5, wherein each rod-like containment formation has a linear base dimension of between 50 and 100 microns and a height greater than or equal to 50 microns.

7. The method of claim 1, wherein said raised containment formations are made of an electrically conductive material, and the method further comprises providing an electrically insulating coating on said raised containment formations made of electrically conductive material.

8. The method of claim 1, further comprising forming said raised containment formations via an additive manufacturing technique.

9. The method of claim 8, wherein the additive manufacturing technique comprises laser induced forward transfer (LIFT).

10. The method of claim 1, further comprising mounting said substrate to a leadframe.

11. A device, comprising:
a substrate;
a first semiconductor die attached to a first die mounting region of a surface of the substrate via reflowed solder material;
a second semiconductor die attached to a second die mounting region of the surface of the substrate via reflowed solder material;
wherein the surface of the substrate includes a clearance area between said first and second die mounting regions; and
raised containment formations at said clearance area on the surface of the substrate, said raised containment formations configured to preclude contact between the first and second semiconductor dice at said clearance area.

12. The device of claim 11, wherein the raised containment formations include two raised containment formations at the clearance area between said first die mounting region and said second die mounting region;

13. The device of claim 11, further comprising:
a connector attached to a connection region of the surface of the substrate via reflowed solder material provided at said connection region, wherein the surface of the substrate includes a further clearance area between the connection region and the first die mounting region; and
further raised containment formations at said further clearance area on the surface of the substrate between the first semiconductor die and the connector.

14. The device of claim 13, wherein:
the raised containment formations include two raised containment formations at the clearance area between said first die mounting region and said second die mounting region; and
the further raised containment formations included two further raised containment formations at the further clearance area between said connection region and said first die mounting region.

15. The device of claim 14, wherein the surface of the substrate is coplanar across the first die mounting region, the second die mounting region, the clearance area and the further clearance area.

16. The device of claim 11, wherein the raised containment formations include rod-like containment formations.

17. The device of claim 16, wherein each rod-like containment formation has a linear base dimension between 50 and 100 microns and a height greater than or equal to 50 microns.

18. The device of claim 11, wherein said raised containment formations are made of an electrically conductive material, and further comprising an electrically insulating coating on said raised containment formations.

19. The device of claim 11, further comprising a leadframe, wherein the substrate is mounted to the leadframe.

20. The device of claim 11, wherein the surface of the substrate is coplanar across the first die mounting region, the second die mounting region and the clearance area.
